(19) United States
(12) Patent Application Publication
(10) Pub. No.: US 2007/0023923 A1
(43) Pub. Date: Feb. 1, 2007

(54) Flip chip interface including a mixed array of heat bumps and signal bumps

(76) Inventor: Peter C. Salmon, Mountain View, CA (US)

Correspondence Address: Edward N. Bachand;DORSEY & WHITNEY LLP, Suite 1000, 555 California Street, San Francisco, CA, 94104-1513, US

(21) Appl. No.: 11/494,811

(22) Filed: Jul. 27, 2006

Related U.S. Application Data
(60) Provisional application No. 60/704,762, filed on Aug. 1, 2005.

(51) Int. Cl. H01L 23/48

(52) U.S. Cl. 257/778

(57) ABSTRACT

A flip chip interface is described between a semiconductor chip and a substrate having interconnection circuits. Flip chip bumps are provided at the active face of the chip; each bump is preferably a flexible copper pillar fabricated on a pad, and terminating at the substrate in a well filled with conductive material. The conductive material may be a conductive powder during testing and rework, converting to a melted solder in the final assembly. A mixed array of pillars is provided: signal pillars for signals and power, and more closely spaced heat pillars for conducting heat away from the chip. The signal pillars may be provided in row and column arrays on a background of heat pillars, and the layout of pillars may be adjusted to match local heat patterns in the chip.

This application claims priority to U.S. provisional patent application Ser. No. 60/704,762 filed Aug. 1, 2005, the entire contents of which are hereby incorporated herein by reference.

### FIELD OF THE INVENTION

This invention relates to electronic packaging, and more particularly to a combination of heat connectors and electrical connectors provided at a flip chip interface between a die and a substrate.

### DESCRIPTION OF THE RELATED ART

Over the last 40 years transistor density in silicon integrated circuit (IC) chips has increased by a factor greater than 100,000; this phenomenon is known as Moore's Law. Meanwhile, the ability to integrate silicon chips into systems has progressed relatively slowly. Package development can be traced from printed circuit boards (PCBs) having plated through holes (PTHs) around 1970. Surface mount technology (SMT) has followed, also multi-chip modules (MCMs), and systems in package (SIPs). The slow rate of development of integration methods compared with silicon fabrication has resulted in an integration gap; this gap has dimensions of cost, performance, cooling, and scalability.

The 2003 International Technology Roadmap for Semiconductors (ITRS) shows packaging costs for microprocessor circuits exceeding chip costs in 2010. Digital IC chips can now operate at signaling rates of 10 Gbps while many packages do not support speeds greater than around 200 Mpbs. Cooling has become critical. Modern servers typically have bulky finned aluminum heat sinks surrounding each of the processors. This increases the volume of the server units with attendant cost increases and performance decreases. Recent microprocessor chips dissipate as much as 150W each. Cooling costs for a 30,000 square foot data center are reported at $8 million per year. Scalability has not been much discussed at the system level, apart from providing servers in a blade form factor for higher packaging density and user convenience. Generally, system or subsystem scalability is difficult if multiple component types and packages are employed.

Electrical connections to an IC chip have typically occurred on the front side of the chip where the active circuits and bonding pads are located, while cooling has been provided at the back side. Thermal interface materials (TIMs) such as thermal grease have been used between the back side of the die and its heat sink. When thermal grease is used, it is typically the highest impedance element in the thermal path.

### SUMMARY OF THE INVENTION

A flip chip interface is described for attaching a chip to a substrate. Each flip chip connector has a pillar in well (PIW) construction. The pillars are formed at input/output (I/O) pads of the chip. A matching well is provided in the substrate for each pillar on the chip. The wells are filled with conductive material that may be a dry powder during testing and rework, converting to melted solder in a finished module. A mixed array of PIW connectors is provided at the chip-to-substrate interface. The mixed array includes signal pillars carrying signals or power, and heat pillars at increased density for cooling the chip. Three levels of cooling are provided, ranging from 9W/cm² using signal pillars, to 160 W/cm² using heat pillars, to over 1000W/cm² using copper slugs on the back side of the chip for hot spots.

### BRIEF DESCRIPTION OF THE DRAWINGS

The foregoing and other objects of the invention will be more clearly understood from the accompanying drawings and description of the invention:

FIG. 1 is a cross-sectional view of a stacked subsystem of the current invention, including embedded cooling channels.

FIG. 2A is an enlarged cross-sectional view of region A of FIG. 1.

FIG. 3 is a cross-sectional view corresponding to section AA of FIG. 2.

FIG. 4 is similar to FIG. 3, except some solder balls have been replaced with fiber optic connections.

FIG. 5 shows an expanded cross-sectional view of a fiber optic connector of FIG. 4.

FIG. 6 shows in cross-section a further expanded view of a fiber optic connector that employs both heat bumps and I/O bumps.

FIG. 7 depicts in cross-section a fiber optic connection that does not require a glass window.

FIG. 8 shows in cross-section a stack of subsystems, with a fiber optic connection to each subsystem.

FIG. 9 illustrates in cross-section the use of a semiconductor plug device in a module.

FIG. 10 shows an expanded schematic cross-sectional view of the plug device of FIG. 9.

FIG. 11 is a schematic view of section BB of FIG. 2, showing an interface between a chip and a substrate that includes a mixed array of I/O bumps and heat bumps.

FIG. 12 is an expanded cross-sectional view of section CC of FIG. 11.

FIG. 13 is a further expanded cross-sectional view of Detail D of FIG. 12.

FIG. 14 is an expanded cross-sectional view showing the use of a damping layer.

FIG. 15 is a top view of a square copper panel showing a layout of multiple copper substrates on a circular copper wafer to be separated from the square panel.

FIG. 16A-16F depicts in cross-section a series of process steps for fabricating a hermetic copper substrate of the current invention having glass-isolated copper feedthroughs.

FIG. 17A-17P depicts in cross-section a series of process steps for fabricating a 5-layer interconnection circuit plus and a well layer on the copper substrate of FIG. 15D, and also forming a solder ball at each feed through, and assembling a chip on the interconnection circuit.

FIG. 18 shows a subsystem stack in cross-section, including a directed source of hot inert gas for removing a defective module.

### DETAILED DESCRIPTION OF THE PREFERRED EMBODIMENTS

Various embodiments of the present invention are described hereinafter with reference to the figures. It should be noted that the figures are only intended to facilitate the description of specific embodiments of the invention. They are not intended as an exhaustive description of the invention or as a limitation on the scope of the invention. In addition, an aspect described in conjunction with a particular embodiment of the present invention is not necessarily limited to that embodiment and can be practiced in any other embodiments. For instance, the preferred embodiment describes cooling of the high power laser diodes in the electro-optic chip using heat bumps at the front face of the chip. However, additional cooling may be applied through the back face of the chip, using a thicker chip or a copper slug, as described relative to other circuit elements of the current invention.

A preferred embodiment of the current invention is a stacked system or subsystem employing modules comprising copper substrates and arrays of flipped chips, with inter-stack cooling channels provided between each pair of modules in the stack. Conventional system components such as PCBs and discrete packages are eliminated. The system is assembled from semiconductor chips and copper substrates having interconnection circuits fabricated thereon. Preferably all of the integrated circuit types including digital, analog, RF, integrated passives, optical, and electro-optical are provided on IC chips that attach using the same type of PIW connector.

The PIW connector employs a pillar or a bump inserted into a well filled with conductive material. It is described in U.S. Pat. No. 6,881,609 for the case of gold stud bumps and solder as the conductive material in the wells. The bumps are usually provided on the IC chips and the wells are provided on the substrate to which the chips are attached, although the reverse can also be employed. The current description of PIW employs a flexible copper pillar for the bump instead of a gold stud bump. The pillar is formed by electro-deposition as a thin wire-like element having flexibility for relieving stress at the interface between chip and substrate. By providing this stress relief using flexible pillars, columns, mesas, or bumps, the typical requirement for an epoxy under layer is avoided; this makes easy rework possible. Testing of known good die (KGD) can be accomplished at full power and full speed by filling the wells with a conductive dry powder. Modules including multiple chips can be assembled and tested in this temporary form of the final assembly, with convenient replacement of any chips that prove defective. For production units, a semi-permanent connection is made by heating the dry powder to form solder; this can be accomplished in one step for an entire subsystem assembly. Even the melted solder connections can be reworked if necessary. This is done be selectively applying heat to melt the solder attaching a defective component. The defective component is withdrawn from the wells, the remaining solder is sucked out of the wells, the wells are refilled and a replacement chip is attached. By using these temporary and semi-permanent connections, complex assemblies with 100 or more chips can be assembled with 100% assembly yield. This avoids rejection of modules or subsystems due to imperfect yield of the component chips. Thus a cost benefit is achieved for modules having up to approximately 6 chips where the compound yield is satisfactory, and an enabling technology is achieved for extending module complexity to modules having 100 chips or more, for example.

For complex flip chip assemblies it is difficult or impossible to test them at full power and full speed through a cable to an external test box. Use of a typical test connector and cable tends to negate the miniaturization advantages of flip chip. Also, it is difficult to drive and sense high speed signals through conventional cables and connectors due to their parasitic inductance and capacitance, particularly as chip technology progresses toward lower power supplies and reduced noise margins. For the systems described herein it is preferable to provide test chips resident in the modules; they will include high speed sampling circuits and comparators and an interface to a test support computer. This testing approach is described in co-pending U.S. patent application Ser. No. 10/448,611, and is incorporated herein in its entirety by reference.

The current invention is a method for providing a mixed array of flip chip connectors at the interface between each chip and its underlying substrate. The mixed array provides both input/output (I/O) capabilities and heat sinking capabilities on the active (front) side of the IC chip. A regular array of bumps (pillars) can be formed in rows and columns to create a sea of bumps, of which selected ones are used for I/O, and the others are used for heat-sinking. Modern microprocessor chips may require 2,000 leads or more, combining both signal and power pins. The PIW connectors can be configured in a small size that will support digital signaling rates of around 20 Gbps.

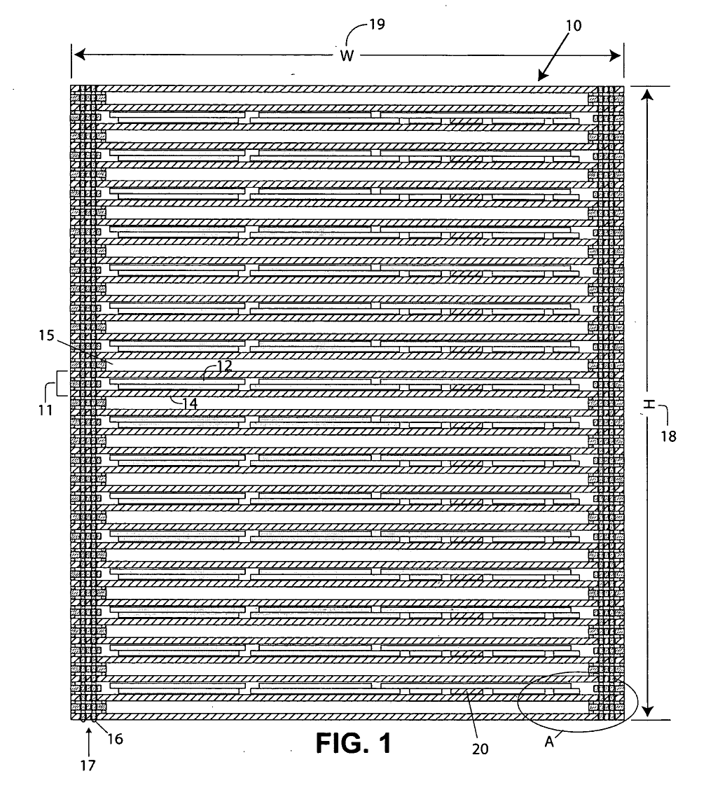

FIG. 1 shows a stacked electronic assembly (subsystem) 10 of the current invention. Subsystem 10 includes hermetic modules 11 containing IC chips 12. Modules 11 at different levels in the stack may be similar to perform a similar function, or may be different to perform different functions. Modules 11 are preferably built on copper substrates 14 and are preferably separated by inter-stack cooling channels 15 through which a coolant may flow. Modules 11 and cooling channels 15 are preferably hermetically sealed (hermetic), to prevent any moisture reaching IC chips 12 as well as to contain the coolant without leakage. As examples, the coolant fluid may be air or water or liquid metal. Cooling channels 15 may be provided between each pair of modules 11, or may be selectively included between high power modules, and not included between low power modules. Subsystem 10 may interface with a PCB or other electronic component using solder balls 16 arranged to form a ball grid array (BGA). The BGA interface provides power and signal I/O to stacked assembly 10, and the stacked BGA connectors 17 provide distribution throughout subsystem 10. PIW connectors may be used in place of the BGA connectors, although a sealing type of connection is required to contain the coolant in cooling channels 15, and this is typically achieved using solder. Thus, a hybrid of PIW electrical connectors combined with solder-type sealing connections may be employed. A typical height H 18 for subsystem 10 including sixteen modules 11 is 60 mm with a typical width dimension W 19 of 50 mm. An example subsystem 10 may be a 64-way computer server wherein each module 11 contains around 80 IC chips and implements a 4-way server. The suite of IC chips within module 11 may include processors, I/O and legacy controllers, memory chips of various types (flash and DDR RAM for example), power distribution chips, one or more test chips, and integrated passives. Compared with servers that are currently available in a blade format (like the IBM HS40 which is a 4-way blade server), modules 11 are smaller and lighter by a factor of more than 100. As will be further explained, modules 11 and subsystem 10 are also testable and repairable, including repair of any chip in any module.

Subsystem 10 will be more reliable than conventional subsystems because of its electrical, mechanical, and thermal design. This is briefly described here in the context of FIG. 1 and further elaborated in the following paragraphs. A new type of flip chip connector (the PIW connector) is used to attach each of the I/O chips such as 12. A similar PIW connector is used for both I/O and for heat extraction. The PIW connector includes a slender copper column (bump) that is flexible enough to relieve shear stresses at the chip/substrate interface. The flexibility (compliance) of the copper column eliminates reliability issues such as cracking of the solder joints due to thermally induced mechanical stress. Also, epoxy under fill is not required and this is an important enabler of an effective rework strategy, for replacing a component that proves to be defective. The copper base plates provide a rugged mechanical design, yet compliance in the flexible copper bumps makes the modules resistant to vibration and shock damage. The thermal design includes options for cooling high thermal fluxes, to be further described. Tight control of junction temperatures leads to increased circuit reliability which is a strong function of peak operating temperature. Finally, by eliminating conventional cables and connectors, subsystem reliability is further improved.

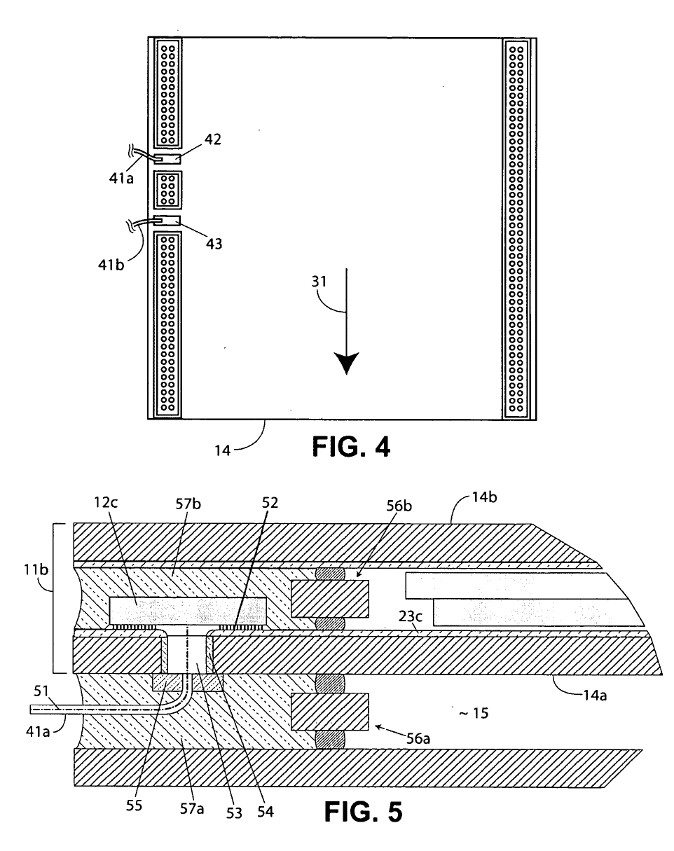

The scalability of subsystem 10 is apparent from its modular construction; the stacking unit is a 4-way server in the preferred embodiment. It can be envisaged that a 256-way server would comprise a stack having four times the height of subsystem 10, for example. It is anticipated that such a 256-way server would require more I/O than a 64-way server; in this case the footprint may be increased, accommodating more I/O at the BGA interface. Since solder bumps and copper feedthroughs have high current capacity, the number of BGA connectors needed for distributing power may not need to increase, allowing the additional pins to be used for I/O. As an alternative solution that will accommodate high bandwidth signals, fiber optic communication ports will be described in reference to FIG. 4 through FIG. 8.

Compared with a typical electronic subsystem of today, the usual printed circuit boards and discrete packages have been eliminated. Subsystem 10 has been assembled from IC chips and copper substrates with interconnection circuits that will be further described. This requires that all circuit components be provided in the form of IC chips, including integrated devices like computing cores, memory chips, power distribution chips, and integrated passives, as well as discrete devices such as resistors, capacitors, inductors, power diodes and power transistors. It also requires innovations in test, assembly and rework, as will be further described. However, elimination of conventional packages and boards reduces cost. The board of the current invention can be viewed as the combination of a high density interconnection (HDI) circuit and a heat dissipation device. Other manufacturing cost advantages are achievable using new testing and rework methods, to be further described.

Because of their small size, the I/O connectors will have a low inductance of approximately 0.1 nH, and this will enable digital signaling rates of around 20 Gbps as well as RF connections operating at frequencies up to around 10 GHz.

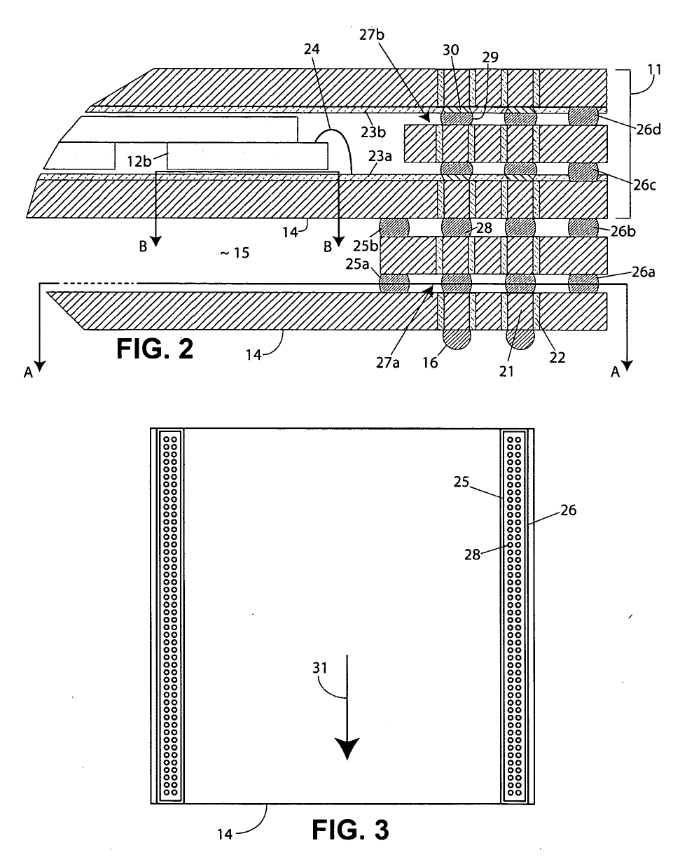

FIG. 2 is an expanded cross-sectional view of region A of FIG. 1. It details a portion of module 11, employing copper substrates 14. Cooling channel 15 is shown, and solder ball 16 of a BGA interface. Copper feedthrough 21 is isolated from copper substrate 14 by a glass seal 22, to be further described. IC chips such as 12b are mounted using a flip chip attachment to interconnection circuit 23a, to be further described. If the backside of a chip requires a bias voltage, it can be provided using a wire bond 24 to a corresponding pad on interconnection circuit 23a. Solder elements 25a and 25b are lines of solder that provide a hermetic seal at the edges of coolant channel 15. Similarly, solder elements 26a and 26b are lines of solder that seal at the outer edges of coolant channel layers, thus keeping feedthroughs like 27a dry. Solder elements 26c and 26d are also lines of solder; in this case their function is to keep the interior of module 11 dry. Feedthroughs like 27b within module 11 have a slightly different structure from feedthrough 27a. Solder bump 28 connects between two copper feedthroughs with no interconnection circuit present. Conversely, solder bump 29 connects to a trace on interconnection circuit 23b through a copper pad 30 embedded in the interconnection circuit. Note that interconnection circuits of the current invention include polymer dielectric layers that are not impervious to water; thus they are not present at the hermetic sealing elements.

FIG. 3 corresponds to section AA of FIG. 2. Copper base plate 14 is shown, together with solder features 25, 26, and 28 defined in FIG. 2. Coolant flow is unobstructed in the direction shown, 31.

FIG. 4 shows a variation of FIG. 3 wherein some of the solder bumps have been replaced with optical connections to increase the I/O bandwidth of module 11 of subsystem 10. Optical fibers 41a and 41b are shown. For example, circuit 42 may implement an optical receiver and circuit 43 may implement an optical transmitter. Again, coolant flow 31 is unobstructed.

FIG. 5 illustrates in cross-section an expanded view of optical circuit 42 of FIG. 4, including optical fiber 41a and light path 51. Electro-optic chip 12c is directly attached to interconnection circuit 23c using PIW flip chip connectors 52, to be further described. For improved heat dissipation, chip 12c may be increased in height to provide cooling through the back face of the die to copper substrate 14b, or alternatively, a copper slug like 20 of FIG. 1 may be employed. A clear glass window 53 is provided in copper substrate 14a for transmitting light signal 51. Glass window 53 is sealed in substrate 14a using a glass seal 54, to be further described. An alignment cap 55 is used to position the end of fiber optic cable 41a in proper relation to electro-optic chip 12c. Hermetic structure 56a seals an edge of coolant channel 15, and hermetic structure 56b seals the complement of chips provided in subsystem 11b. Filler materials 57a and 57b are used to stabilize the structures after assembly; they are non-conducting and preferably good thermal conductors. A disadvantage of module 11b compared with module 11 of FIG. 1 is increased difficulty of rework, owing to the presence of filler 57b. Another disadvantage is the lack of a hermetic environment for electro-optic chip 12c. However, providing high bandwidth optical connections is important enough that these disadvantages may be acceptable.

Optical alignment of light path 51 with electro-optic chip 12c can be accomplished in two steps. First, the basic alignment accuracy of the PIW connectors is around ±5 μm. A performance parameter of the optical link (such as signal to noise ratio, SNR) is monitored while the solder is melted and the fine positioning of the chip attachment is optimized for link performance. The initial alignment and the fine-tuning feature depend on features of the PIW connector, to be further described.

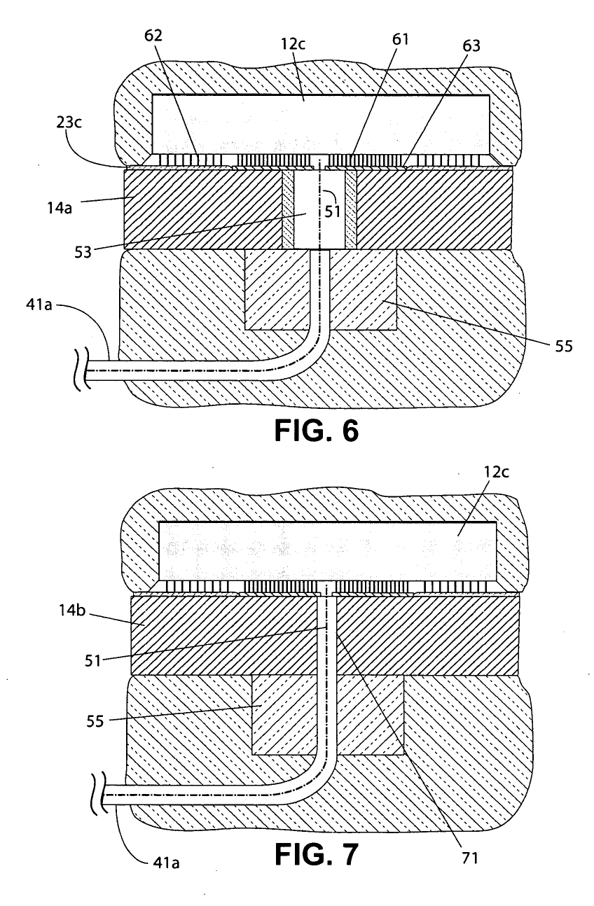

FIG. 6 is a further expanded cross-sectional view of a preferred direct chip attachment of electro-optic chip 12c with interconnection circuit 23c. In FIG. 6 this attachment includes a combination of heat bumps 61 and input/output (I/O) bumps 62 as shown. The heat bumps are densely packed for maximum heat conduction and the I/O bumps are spaced apart to create separate electrical connections, to be further described. Heat bumps 61 terminate on a copper pedestal 63 while I/O bumps 62 terminate in interconnection circuit 23c.

FIG. 7 shows a variation on the fiber optic attachment depicted in FIG. 6. A precisely located and aligned hole 71 is provided in copper substrate 14b for capturing the end of optical fiber 41a while providing good alignment of light path 51 as it enters or exits from electro-optic chip 12c. As will be further described, the process used to machine copper substrate 14b can create alignment hole 71 with a placement accuracy of around ±1 μm using available milling machines. Using this placement accuracy together with a process for fine-tuning the optical alignment, as described in reference to FIG. 5, good optical alignment can be achieved while avoiding the cost of fabricating the clear glass window 53 shown in FIG. 6.

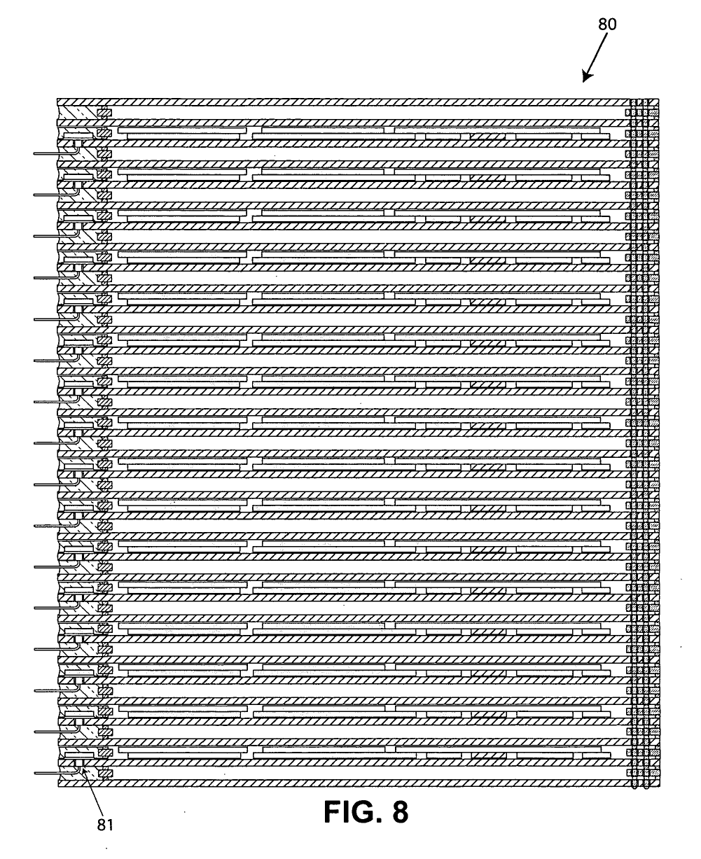

FIG. 8 shows a stacked subsystem architecture 80 of the current invention wherein each of the modules in the stack has a fiber optic connection 81 for increased I/O bandwidth.

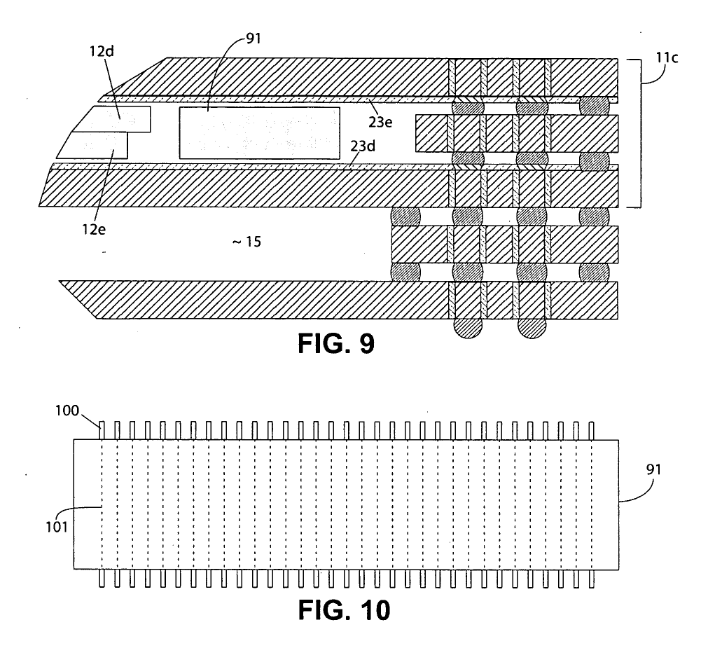

FIG. 9 illustrates the use of a semiconductor plug 91 for communicating high bandwidth signals between interconnection circuits 23d and 23e of module 11c. Chips 12d and 12e are thinned to approximately one half of the thickness of plug 91 so that the different chips fit well together in module 11c as shown.

FIG. 10 is a schematic representation of plug 91 including copper bump (pillar) element 100, and feedthrough element 101. Various methods are known in the art for creating feedthrough element 101 using either polysilicon or copper as the feedthrough conductor. Detailed features of bump element 100 will be further described.

FIG. 11 corresponds to section BB of FIG. 2; it is a cross-section representing an interface between a chip and a substrate. A background array 111 of heat bumps is shown; it is comprised of copper columns that are closely spaced for maximum heat conduction and bend individually to relieve stress at the interface. I/O bumps are arrayed in rows and columns like 112; the I/O bumps are spaced apart and connect to substrate nodes individually, as will be further described. The layout shown in FIG. 11 represents a default or starting condition; it can be adjusted as required in response to routing issues and thermal issues. Note that the default layout shown in FIG. 11 provides a signal connector within a millimeter or two of any location on the chip; this means that signal path lengths can be short, aiding high frequency operation.

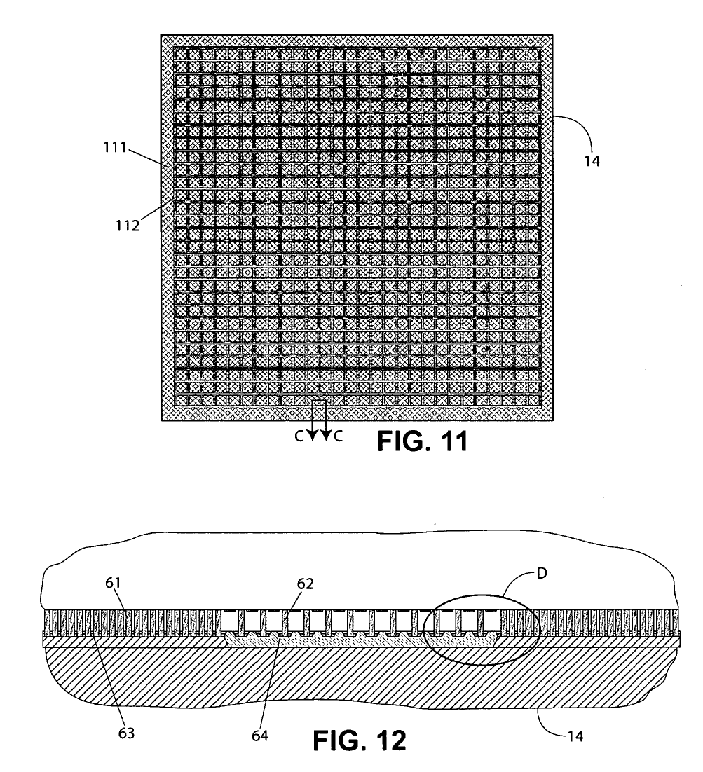

FIG. 12 is an expanded cross-sectional view corresponding to section CC of FIG. 11. Heat bumps 61 and I/O bumps 62 are shown. Heat bumps 61 terminate at the substrate in a common well 63 filled with conductive material. I/O bumps 62 terminate at the substrate in individual wells 64 filled with conductive material.

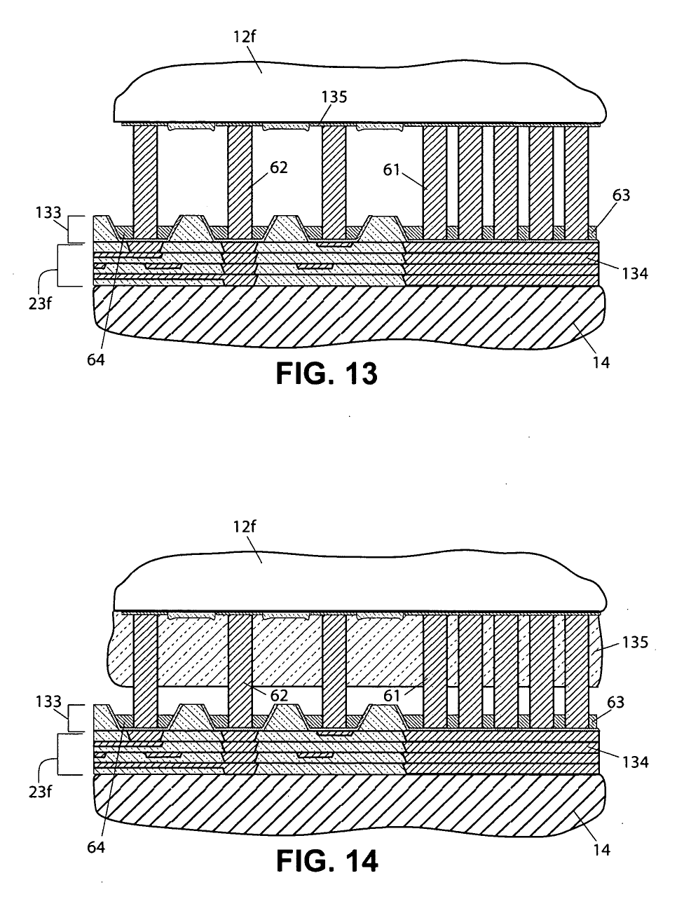

FIG. 13 is a further expanded cross-sectional view corresponding to Detail D of FIG. 12. Both heat bumps 61 and I/O bumps 62 are slender copper pillars that can flex to relieve stress at the interface. The bumps are anchored on pads 135 located on the front face (active side) of chip 12f. A preferred height-to-width ratio for both kinds of bumps is 5-10. A preferred height is 100 μm, because calculations show that around 32 μm of lateral translation is required at the edge of a large chip undergoing typical temperature cycles during manufacture; a height of 100 μm provides enough extension and flexibility to accomodate this motion. In addition to the lateral motion, about 6 μm of vertical translation is also required to relieve the interface stress, allowing an attached chip to remain flat; the columns are preferably flexible enough that they will bend or buckle as required to relieve this stress in the vertical direction. A preferred pitch for the I/O connectors is 80 μm, providing over 15,000 connectors per square centimeter. This density provides enough connectors for good localized power distribution. The extra connectors can also help to lower signal cross-talk, by surrounding each signal connector with a set of nearest-neighbor GND or DC power connections. A preferred pitch for the heat bumps is 30 μm, providing over 100,000 bumps per square centimeter. A suitable plating resist for achieving these geometries is Clariant Exp 100XT. It is a positive resist that is easily stripped after the copper columns are formed. The resist can be patterned with essentially vertical sidewalls at 100 μm thickness.

Common well 63 is provided for terminating the heat bumps at the substrate surface, and an individual well 64 for each I/O bump is shown. An example of an interconnection circuit 23f is shown. The well layer is shown as 133. Heat bumps 61 thermally connect with a copper pedestal 134 for maximum heat conduction from IC chip 12f to copper substrate 14. As will be further described, each bump originates at a pad like 135 on the chip. Note that bumps 61 and 62 combine mechanical, electrical, and thermal functions. Mechanically they provide structural support, stress relief, and compliant resistance to vibration and shock. Electrically they provide low inductance connectors estimated at 0.1 nH per bump/well combination; thus they will support digital signaling at around 20 Gbps and RF circuits operating at multi-gigahertz frequencies. Thermally they can dissipate heat flux ranging from 9 W/cm² for signal bumps alone, to 160 W/cm² for densely packed heat bumps, and to over 1,000 W/cm² when copper slugs like 20 in FIG. 1 are employed. These calculations assume a liquid coolant temperature of 10° C. and a maximum junction temperature of 85° C. Without resorting to the use of copper plugs, or using them only sparingly, subsystems like 10 of FIG. 1 can dissipate over 10 kW, while running efficiently and reliably. This multi-function performance can enable a new technology platform wherein digital and RF components are integrated using the same PIW connector. The preferred technology platform also includes copper substrates and high density interconnection circuits and test chips, to be further described.

FIG. 14 shows the use of a damping layer 135 of dielectric material such as polyimide, fabricated on chip 12f and substantially filling the space around pillars 61 and 62, except for ends of the pillars that are inserted into the wells. Damping layer 135 provides a compliant support structure that does not substantially interfere with the stress-relieving properties of the compliant pillars, yet provides additional protection against shock and vibration, and adds another thermally conductive path to aid in transporting heat between chip 12f and substrate 14.

This disclosure will now describe manufacturing processes for building the preferred modules and subsystems, along with a test method and a rework method for the stacked architecture.

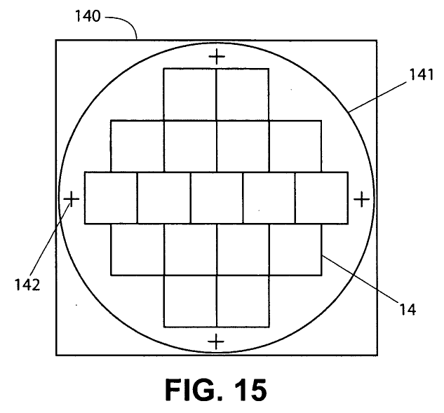

FIG. 15 is a top view of a square copper panel 140, preferably measuring 305×305×0.8 mm. Inscribed on panel 140 is a circular copper wafer 141 that is 300 mm in diameter. Inscribed within wafer 141 are seventeen copper substrates 14 measuring 50×50 mm. These dimensions take advantage of available fabrication equipment for processing 300 mm semiconductor wafers; however, any practical size of panel 140, wafer 141, and substrate 14 are included in the current invention. Alignment marks 142 are also provided; along with the wafer and substrate outlines they are inscribed (machined) into the copper surface during milling steps to be described.

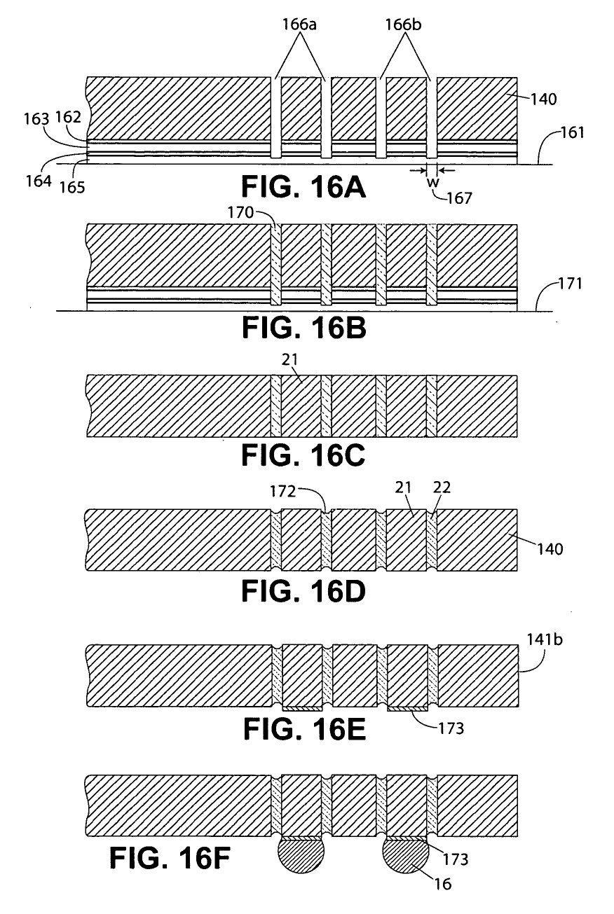

FIG. 16A-16F illustrates a process sequence for fabricating isolated copper feedthroughs, starting with copper panel 140. FIG. 16A shows a vacuum hold-down surface 161 of a milling machine such as an H100 available from LPKF Laser and Electronics, Wilsonville, Oreg., USA. This machine spins the cutting tool at 100,000 RPM and is capable of milling tracks as narrow as 0.0031 inches or 80 μm. It also has a repetition accuracy of ±1 μm. Copper panel 140 of FIG. 15 is affixed to vacuum surface 161 using two mounting tapes that are pre-applied to the copper panel. The first tape is preferably a thermal release tape such as Revalpha available from Nitto Denko, Tokyo, Japan. It has a thermal release temperature of 150° C. for example. After removing its liner, this tape includes thermal release layer 162 (which is adhesive) and base polyester layer 163. The second applied tape has an adhesive layer 164 and a porous backing layer 165. After mounting copper panel 140 to vacuum surface 161 using the two mounting tapes, the milling tool is programmed to cut cylindrical cavities such as 166a and 166b that penetrate into porous layer 165 but do not interfere with vacuum surface 161. The preferred thickness of panel 140 is 0.8 mm and the preferred cavity width, w 167, is 0.1 mm.

FIG. 16B shows the effect of screening a glass frit material 170 into the machined cavities. This process is preferably performed using a vacuum table 171, which will help fill the cavities to the bottom.

FIG. 16C shows the result of activating the thermal release layer and removing both of the tapes from the back side of copper panel 140. The stiffness of the screened frit material is adequate to hold copper feedthroughs 21 in position while both mounting tapes are released using a hotplate.

FIG. 16D shows the result of firing the glass frit to form glass seals 22 around copper feedthroughs 21, as first defined in FIG. 2. An inert atmosphere is used for this firing at around 550° C., to prevent excessive oxidation of base copper panel 140. The screened frit material will reduce in volume when fired, forming a cupped surface 172 as shown. Copper wafer 141b will be separated from the copper panel 140 using the milling tool, employing alignment marks 142 previously described in reference to FIG. 15. Chemical mechanical polishing (CMP) will be applied as is known in the art, to polish the separated copper wafer to a final preferred thickness of 0.6 mm.

FIG. 16E shows an under bump metallization (UBM) 173 applied to the copper feedthroughs as shown. UBMs are known in the art; a typical formulation includes a thin titanium layer for adhesion, nickel as a diffusion barrier, and gold to provide a solder wetting surface.

FIG. 16F shows copper substrate 14 with solder balls 16 formed on UBM layer 173. Since the solder balls would prevent vacuum hold-down on chucks used for processing the interconnection circuits on copper wafer 141b, process steps described in relation to FIGS. 16E and 16F are delayed until the interconnection circuits are completed. The solder balls may be formed using wafer level stencil printing, jetting processes, or electroforming, all known in the art. When the deposited solder alloy is heated to melting, it is pulled into a spherical shape by surface tension. After bumping wafer 141b with solder balls, it can be separated into individual module substrates 14 using the milling tool previously described.

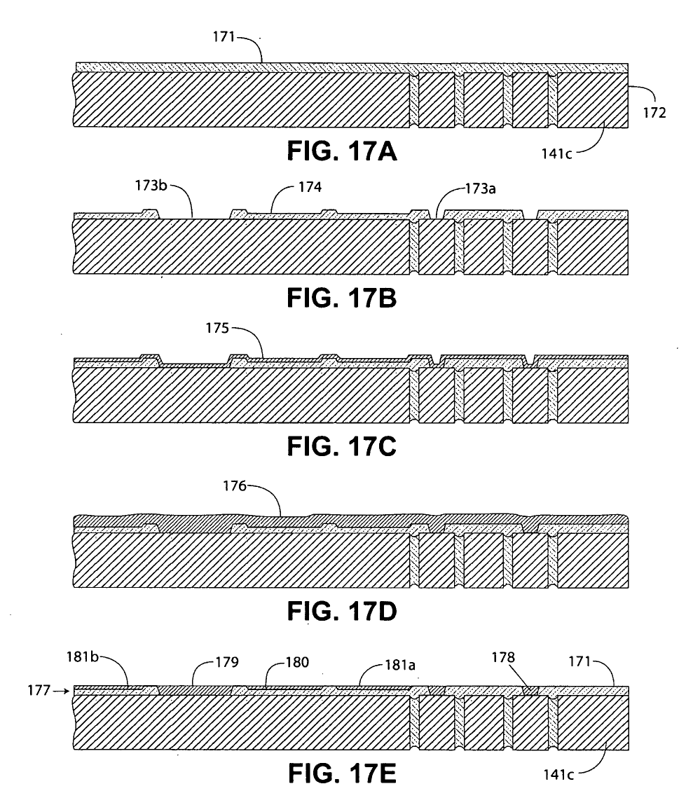

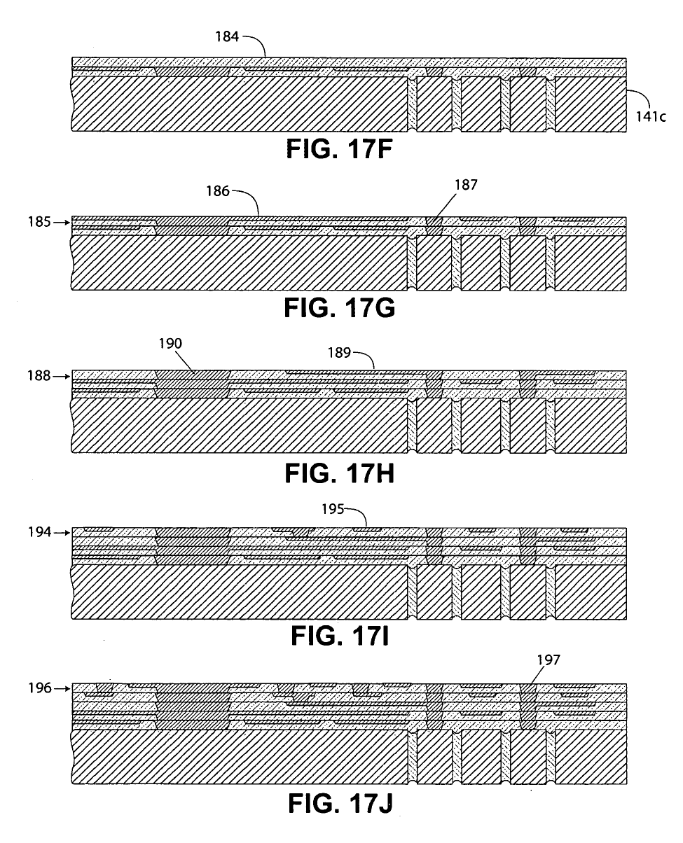

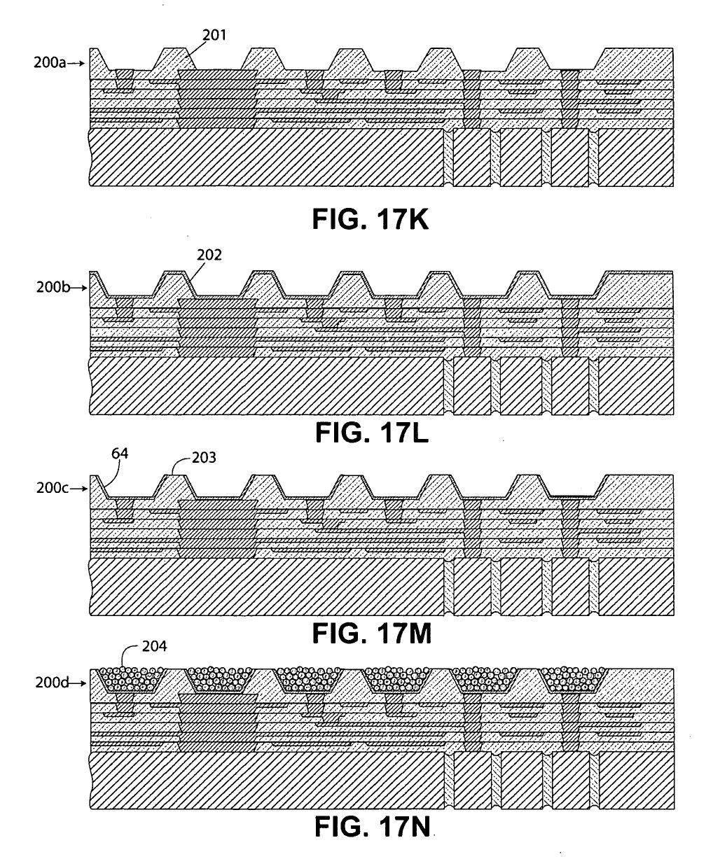

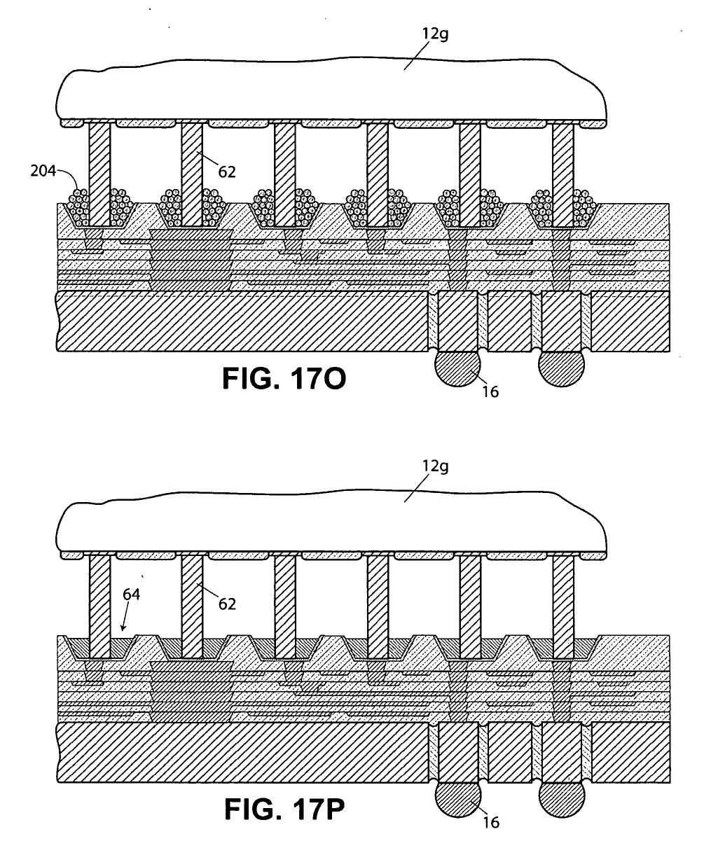

FIG. 17A-17P illustrates a process sequence for fabricating interconnection circuits and a well layer on a copper wafer. FIG. 17A-17E teaches the base processes for fabricating a single dual damascene copper layer, of which five are included in the preferred embodiment of the current invention. For visual reference in FIG. 17A-17P an edge 172 is shown, although this edge is not created until wafer processing is completed and substrates 14 are separated from wafer 141c.

FIG. 17A shows the result of spin coating copper wafer 141c with a preferred spin-on dielectric (SOD) material 171 called BCB (benzocyclobutene), which is well known in the industry. Polyimide may be used in place of BCB. The preferred thickness is approximately 8 μm.

In FIG. 17B, layer 171 of BCB has been patterned using dual damascene processes, forming via features 173a and 173b, and also trace features 174. Either photolithographic methods or the imprinting method may be used to achieve this result; both are known in the art.

FIG. 17C shows the result of sputter deposition of a seed layer of copper 175, typically using a thin layer of titanium for adhesion to the underlying BCB.

In FIG. 17D, the copper seed layer has been electroplated, terminating in an uneven surface 176.

FIG. 17E shows the result of polishing the surface of wafer 141c using CMP methods known in the art. Power trace layer 177 is complete, including vias 178 and 179, also traces 180. In the preferred embodiment, this layer provides GND plus two power supplies, delivered using via/trace 179 and traces 180a and 181a respectively. These power traces repeat across the substrate surface, and trace 181b delivers the same voltage as 181a. For the special case of the power trace layer 177 depicted in FIG. 17E, embedded capacitance may be valuable for bypassing each power supply to GND. Consequently, a high dielectric material may be used for layer 171 instead of BCB or polyimide. This embedded capacitance technique is also known in the art.

FIG. 17F shows that a new layer 184 of SOD material has been applied to wafer 141c, in preparation for fabrication of a second dual damascene copper interconnect layer.

FIG. 17G shows completed second layer 185 which is a GND layer, to support a transmission line structure for the subsequent signal layer, as is known in the art. Layer 185 includes ground conductors 186 and feedthrough vias 187.

FIG. 17H depicts first signal layer 188, including traces 189 that preferably run in the x-direction. Signal traces are routed around the power and GND vias.

FIG. 17I shows second signal layer 194, including traces like 195 that preferably run in the y-direction.

FIG. 17J illustrates layer 196, including vias 197 that will connect with wells, to be fabricated next.

FIG. 17K illustrates a patterned dielectric layer 201, preferably around 20 μm thick, forming the well shapes for a well layer, 200a.

In FIG. 17L, well layer 200b includes sputter deposited Ti/Au 202 that physically and electrically connects with the underlying copper structures. An outer covering of gold is required for compatibility with the preferred 80Au20Sn solder paste. For reliable solder connections, the Au layer must be at least 1000 Angstroms thick.

FIG. 17M shows the result of CMP to remove the Ti/Au thin films in field areas 203, providing electrical isolation between the wells in layer 200c.

In FIG. 17N, layer 200d shows that the wells have been filled with fine conductive particles 204. The preferred particles are made from a gold-tin alloy, 80Au20Sn. The preferred particle diameter is smaller than 4 μm, for easy filling of the wells 64. 80Au20Sn alloy is lead-free, and has a successful history as a high-reliability solder. Any oxide tarnish on the particles can be removed by dipping in dilute hydrochloric acid; thus providing a flux-free solder. The wells are filled by pouring the conductive powder over the substrate surface to fill all of the wells, then applying and removing a sheet of adhesive to the substrate surface to remove loose particles adhering to areas 203 between the wells.

FIG. 17O shows the result of aligning an IC chip 12g with the substrate containing the wells, bringing them together, and pushing gently on chip 12g so that the pillars 62 penetrate the powder in the wells. For fragile chips such as ones using delicate low-k dielectrics, it may be desirable to apply ultrasonic shaking, so that the pillars enter the powder in the wells using only gravity as a pushing force. The alignment process is known in the art: a precision flip chip aligner using split beam optics can achieve alignment accuracy of around ±2 μm. 80Au20Sn is reported to have tensile strength and shear strength of 40,000 PSI, the highest of commonly available solders. This strength is advantageous for capturing the ends of copper bumps 62 in wells 64 firmly under mechanical stress conditions such as occur during temperature cycling or shock conditions.

FIG. 17P shows the result of melting and flowing the 80Au20Sn solder at approximately 320° C.; the volume of solder shrinks slightly.

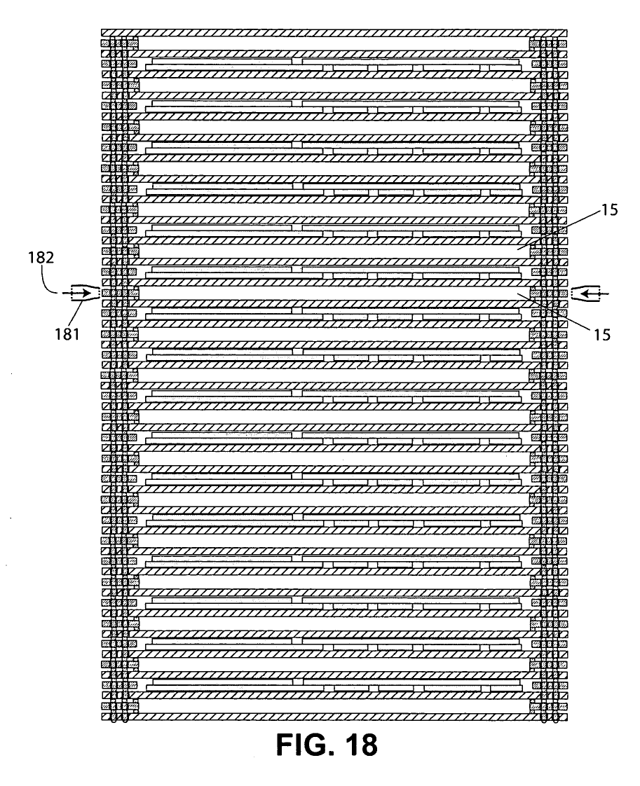

In the event that a large subsystem like 10 of FIG. 1 begins to fail, some disassembly may be required. The resident test chips can be used to isolate which of the modules is defective and needs replacement or repair. FIG. 18 shows schematically how the nozzles of a rework device can direct jets of hot inert gas selectively at a particular set of feedthroughs in the stack. Soldered joints at the chosen level in the stack will melt, allowing disassembly. This process may be aided by flowing hot inert gas through adjacent cooling channels 15. It is preferable to suck out any solder remaining at the interface and replace it with new solder on the replacement parts. The new solder is reflowed to semi-permanently install the replacement module. Defective modules can be repaired by re-working defective chips using the process previously described in relation to PIW connectors.

A stacked 3D electronic subsystem has been described using flip chip attachments comprising mixed arrays of signal pillar and heat pillar connections. The described subsystem can achieve a miniaturization factor of over 100 compared with equivalent assemblies using current technology, yet it can be well-tested, repairable, and adequately-cooled. The described methods can be applied to increase performance and reduce cost, in assemblies as small as cell phones and as large as supercomputers.

What is claimed is:

1. An interface between a semiconductor chip and a substrate comprising:
conductive pillars formed at pads of said chip;
interconnection circuits fabricated on said substrate;
wells corresponding to said pillars formed in or on said interconnection circuits;
conductive material substantially filling said wells; and,
wherein said pillars are inserted into said wells to form a mixed array of lower density connections for signals and power, and higher density connections for conducting heat away from said chip.

2. The interface of claim 1 wherein each of said pillars comprises a column of copper or an alloy of copper.

3. The interface of claim 1 wherein said conductive material in said wells is comprised of particles.

4. The interface of claim 3 wherein said particles comprise a solder alloy.

5. The interface of claim 4 wherein said solder alloy is 80Au20Sn.

6. The interface of claim 1 wherein said conductive material in said wells is a melted solder.

7. The interface of claim 1 wherein the aspect ratio of said pillars is at least three to one, height to width.

8. The interface of claim 1 wherein a dielectric material is formed around said pillars, substantially filling the spaces between them, but leaving an exposed end for insertion in said wells.

9. The interface of claim 8 wherein said dielectric material is compliant, having a low rigidity modulus.

10. The interface of claim 8 wherein said dielectric material is electrically non conductive but is thermally conductive.

11. The interface of claim 8 wherein said dielectric material is polyimide.

12. The interface of claim 1 wherein said lower density connections are substantially arrayed in rows and columns.

13. The interface of claim 1 wherein said higher density connections form a background array that covers said chip except where space is provided for said lower density connectors.

14. A method for mechanically, electrically, and thermally connecting an integrated circuit chip to a substrate comprising the steps of:
a) providing one or more groups of closely spaced heat pillars that are thermally conductivity and originate at conductive pads on the front or active face of said chip;
b) for each of said groups of heat pillars, providing on said substrate a corresponding heat well containing conductive material;
c) providing one or more groups of less closely spaced signal pillars that are electrically conductive and originate at input/output pads on the active face of said chip;
d) for each of said signal pillars, providing on said substrate a corresponding signal well containing conductive material; and,
e) aligning and bringing together said chip and said substrate so that said heat pillars are inserted into said heat wells, and said signal pillars are inserted into said signal wells, and all pillars connect with conductive material in said wells, thereby forming said mechanical, electrical, and thermal connections.

15. The method of claim 14 and including the step of providing a thermally conductive pedestal underneath each of said heat wells, for improved thermal connection to said substrate.

16. The method of claim 15 and including the step of electroforming copper to fabricate said heat pillars and said signal pillars and said thermally conductive pedestals.

17. The method of claim 14 and including the step of filling said wells with conductive material in the form of particles.

18. The method of claim 17 wherein the step of filling said wells with particles comprises the steps of:
flowing said particles over said wells until they are filled; and,
applying and removing an adhesive sheet on the surface of said substrate to remove particles that are not in said wells.

19. The method of claim 18 and including the additional step of heating said particles to form melted solder in said wells.

20. The method of claim 14 wherein said pillars have a height to width ratio of three or greater.
